(19) United States
(12) Patent Application Publication
(10) Pub. No.: US 2024/0152167 A1
(43) Pub. Date: May 9, 2024

(54) SEMICONDUCTOR DEVICE, SEMICONDUCTOR DEVICE SYSTEM, AND MOBILE DEVICE

(71) Applicant: ROHM CO., LTD., Kyoto (JP)

(72) Inventor: Yoichiro NOGUCHI, Kyoto (JP)

(21) Appl. No.: 18/502,372

(22) Filed: Nov. 6, 2023

(30) Foreign Application Priority Data
Nov. 9, 2022 (JP) 2022-179383

(51) Int. Cl. G05F 1/56; H03K 17/687

(52) U.S. Cl. CPC G05F 1/56; H03K 17/6871

(57) ABSTRACT

A semiconductor device includes: a control input terminal configured to receive a control input signal from an external controller; and a current mirror including an input stage and an output stage connected to the control input terminal.

### CROSS-REFERENCE TO RELATED APPLICATION

This application is based upon and claims the benefit of priority from Japanese Patent Application No. 2022-179383, filed on Nov. 9, 2022, the entire contents of which are incorporated herein by reference.

### TECHNICAL FIELD

The present disclosure relates to a semiconductor device.

### BACKGROUND

In the related art, for example, various mobile devices such as an electronic key and the like used in a keyless entry system are often driven by a battery.

### BRIEF DESCRIPTION OF DRAWINGS

The accompanying drawings, which are incorporated in and constitute a part of the present disclosure, illustrate embodiments of the present disclosure.

FIG. 1 is a diagram showing a configuration of a semiconductor device system according to an exemplary embodiment of the present disclosure.

FIG. 2 is a diagram showing a first configuration example for generating a constant current output.

FIG. 3 is a diagram showing a second configuration example for generating a constant current output.

FIG. 4 is a diagram showing a configuration of a semiconductor device system according to a modification.

FIG. 5 is a diagram showing a configuration example of an electronic key.

FIG. 6 is a diagram showing a configuration of a semiconductor device system according to a comparative example.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Exemplary embodiments of the present disclosure will now be described with reference to the drawings.

### 1. Comparative Example

Prior to describing embodiments of the present disclosure, a comparative example will be described for comparison. Issues will become clearer by describing the comparative example.

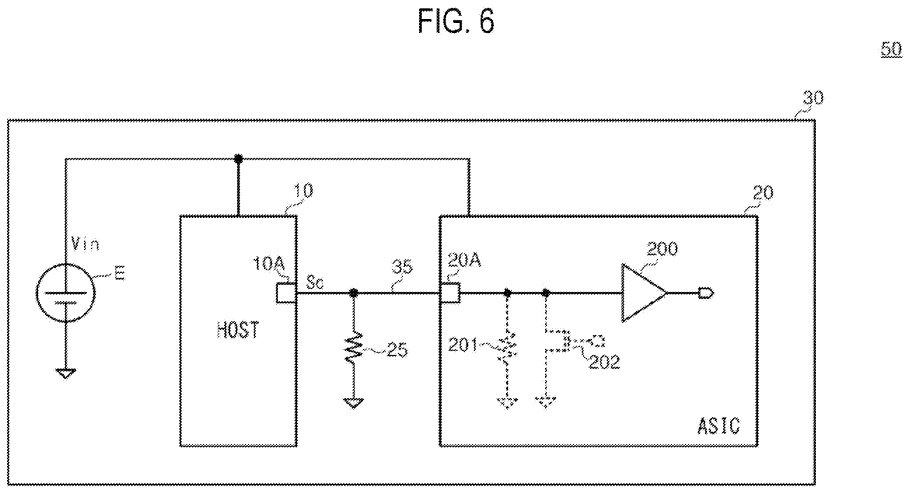

FIG. 6 is a diagram showing a configuration of a semiconductor device system 50 according to the comparative example. The semiconductor device system 50 includes a host 10, an ASIC (application specific integrated circuit) 20, a substrate 30, and a battery E.

The host 10 is a semiconductor device (semiconductor IC) configured as a microcontroller, and is mounted on the substrate 30. The host 10 controls the ASIC 20 by sending various control input signals to the ASIC 20. The host 10 includes a control output terminal 10A provided so as to output a control input signal Sc for switching an enabled state and a disabled state to the ASIC 20. The enabled state indicates an active state of the ASIC 20, and the disabled state indicates an inactive state of the ASIC 20. In FIG. 6, terminals of the host 10 other than the control output terminal 10A are not shown.

The ASIC 20 is a semiconductor device designed and manufactured for a specific use, and is mounted on the substrate 30. The ASIC 20 includes a control input terminal 20A. The control output terminal 10A and the control input terminal 20A are connected by a wiring 35 provided on the substrate 30. The ASIC 20 includes an input part 200. The input part 200 is configured as, for example, an inverter, a Schmitt trigger, or an amplifier. In FIG. 6, terminals of the ASIC 20 other than the control input terminal 20A are not shown.

The control input signal Sc outputted from the control output terminal 10A is inputted to the input part 200 via the wiring 35 and the control input terminal 20A. The enabled state and disabled state of the ASIC 20 is switched depending on the logic level of the control input signal Sc. Specifically, the disabled state is obtained when the control input signal Sc is at a low level, and the enabled state is obtained when the control input signal Sc is at a high level.

The battery E is a power source configured to generate an input voltage Vin which is a DC voltage, and is mounted on the substrate 30. The battery E is configured as a button battery, for example. The input voltage Vin is supplied to the host 10 and the ASIC 20 as a power supply voltage.

Depending on the state of the host 10, the voltage at the control output terminal 10A may become unstable. For example, when the battery E is mounted and the input voltage Vin is activated, the above-described unstable state occurs until the host 10 starts up and the voltage at the control output terminal 10A stabilizes at a high level. Therefore, a pull-down resistor 25 is provided to prevent a voltage at the control input terminal 20A from becoming unstable. The pull-down resistor 25 is mounted on the substrate 30 and connected between the wiring 35 and the ground terminal. In this way, by pulling down the control input terminal 20A, it is possible to prevent the voltage at the control input terminal 20A from being at a low level and being in an unstable state.

However, when the control input signal Sc is at a high level and the ASIC 20 is in an enabled state, for example, when the input voltage Vin is 3 V and the pull-down resistor 25 has a resistance value of 1 MΩ, a current flowing through the pull-down resistor 25 is 3 μA. The battery-driven semiconductor device system 50 requires low current consumption. For example, when current consumption of the entire ASIC 20 is 1 μA, influence of the current flowing through the pull-down resistor 25 is large. Furthermore, an external component such as the pull-down resistor 25 or the like is required.

Further, as shown in FIG. 6, a pull-down resistor 201 built in the ASIC 20 may be provided instead of the pull-down resistor 25. However, to reduce the current flowing through the pull-down resistor 201, it is necessary to increase the resistance value of the pull-down resistor 201. For example, when Vin is 3 V and the current flowing through the pull-down resistor 201 is 30 nA, the pull-down resistor 201 has a resistance value of 100 MΩ, and an element area of about 10,000 μm² is required to form the pull-down resistor 201. That is, the area of the elements provided inside the ASIC 20 increases.

Further, as shown in FIG. 6, a MOS switch 202 built in the ASIC 20 may be provided instead of the pull-down resistor 25. The MOS switch 202 is configured as an NMOS transistor (N-channel MOSFET (metal-oxide-semiconductor field-effect transistor)). By turning on the MOS switch 202, it may be used as a pull-down resistor. However, there are issues in that a configuration for controlling the MOS switch 202 is required inside the ASIC 20 and an element area of the MOS switch 202 becomes large to reduce a current flowing through the MOS switch 202.

In a case where the disabled state is obtained when the control input signal Sc is at a high level, the control input terminal 20A may be pulled up. Although this prevents the voltage at the control input terminal 20A from becoming unstable, in the case of pull-down, issues that are similar to the above-described issues may arise.

### 2. ASIC Configuration

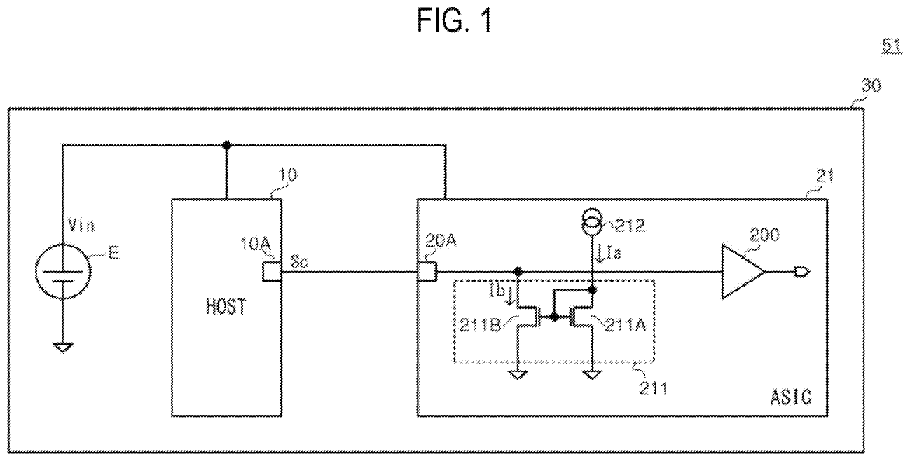

In view of the above issues, embodiments of the present disclosure described below are implemented. FIG. 1 is a diagram showing a configuration of a semiconductor device system 51 according to an exemplary embodiment of the present disclosure. The semiconductor device system 51 includes a substrate 30, a host 10, an ASIC 21, and a battery E.

A difference in configuration between the semiconductor device system 51 and the comparative example described above is an internal configuration of the ASIC 21. The ASIC 21 is provided with a current mirror 211 and a constant current source 212.

The current mirror 211 includes an input stage 211A and an output stage 211B. Both the input stage 211A and the output stage 211B are constituted by NMOS transistors. A drain and a gate of the input stage 211A are short-circuited. A source of the input stage 211A is connected to a ground terminal. Gates of the input stage 211A and the output stage 211B are connected to each other. A source of the output stage 211B is connected to the ground terminal. A drain of the output stage 211B is connected to the control input terminal 20A. The constant current source 212 is connected to a drain of the input stage 211A.

In the semiconductor device system 51, the ASIC 21 is in an enabled state when the control input signal Sc is at a high level, and is in a disabled state when the control input signal Sc is at a low level. A constant current Ia flowing into the input stage 211A by the constant current source 212 is mirrored by the current mirror 211 and becomes a constant current output Ib flowing to the output stage 211B. Since electric charges of the control input terminal 20A are drawn to the ground terminal by the constant current output Ib, the voltage of the control input terminal 20A is set to a low level and is prevented from being in an unstable state. Further, the generated current is a constant current regardless of the voltage level of the control input terminal 20A. A circuit area of the current mirror 211 and the constant current source 212 configured to realize a constant current with a small current value is small. Therefore, low current consumption may be achieved in the ASIC 21.

### 3. Configuration of Constant Current Generation

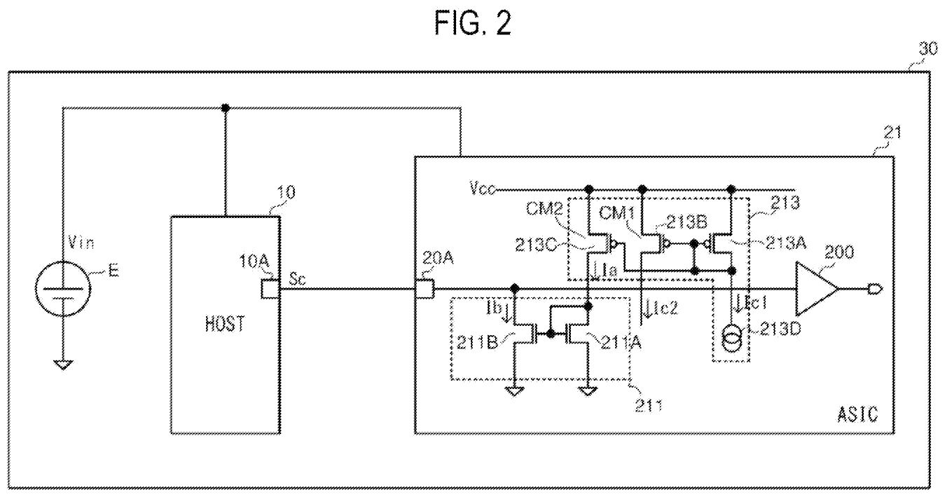

FIG. 2 is a diagram showing a first configuration example for generating a constant current output Ib. In the configuration shown in FIG. 2, a circuit current source 213 is provided inside the ASIC 21. The circuit current source 213 is a circuit configured to generate a circuit current Ic2 which is to be supplied to an internal circuit of the ASIC 21.

The circuit current source 213 includes a current mirror CM1, a current mirror CM2, and a constant current source 213D.

The current mirror CM1 includes a PMOS transistor (P-channel MOSFET) 213A and a PMOS transistor 213B. A gate and a drain of the PMOS transistor 213A are short-circuited. Gates of the PMOS transistor 213A and the PMOS transistor 213B are connected to each other. Sources of the PMOS transistor 213A and the PMOS transistor 213B are respectively connected to an application terminal of a power supply voltage Vcc. The drain of the PMOS transistor 213A is connected to the constant current source 213D.

As a result, a constant current Ic1 flowing through the PMOS transistor 213A by the constant current source 213D is mirrored by the current mirror CM1 to become a circuit current Ic2 flowing through the PMOS transistor 213B.

The current mirror CM2 includes a PMOS transistor 213A and a PMOS transistor 213C. That is, the PMOS transistor 213A is common to the current mirrors CM1 and CM2. Gates of the PMOS transistor 213A and the PMOS transistor 213C are connected to each other. A source of the PMOS transistor 213C is connected to an application terminal of the power supply voltage Vcc. A drain of the PMOS transistor 213C is connected to the drain of the input stage 211A.

As a result, the constant current Ic1 flowing through the PMOS transistor 213A by the constant current source 213D is mirrored by the current mirror CM2 to become a constant current Ia flowing through the PMOS transistor 213C. As described above, the constant current Ia is mirrored by the current mirror 211 to become the constant current output Ib.

In this way, the constant current output Ib may be generated by shunting the constant current Ia from the circuit current source 213. For example, the constant current output Ib is 10 nA, each channel width of the input stage 211A, the output stage 211B, and the PMOS transistors 213A and 213C is 2 μm, each channel length thereof is 20 μm, and an area required for configuring the input stage 211A, the output stage 211B, and the PMOS transistors 213A and 213C is approximately 100 μm². Thus, the circuit area may be reduced.

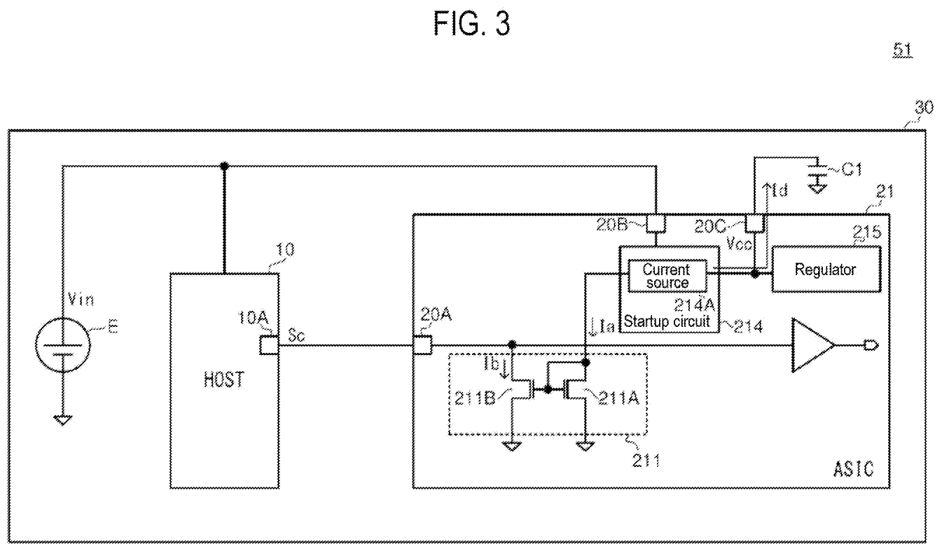

FIG. 3 is a diagram showing a second configuration example for generating the constant current output Ib. In the configuration shown in FIG. 3, a startup circuit 214 and a regulator 215 are provided inside the ASIC 21. The ASIC 21 includes an input voltage terminal 20B and a power supply terminal 20C in addition to the control input terminal 20A. A capacitor C1 is externally connected to the power supply terminal 20C.

The input voltage Vin is externally inputted to the startup circuit 214 via the input voltage terminal 20B. When the battery E is mounted and the input voltage Vin is activated, the startup circuit 214 is started up. The startup circuit 214 is configured to supply a startup current Id to the capacitor C1 via the power supply terminal 20C. As a result, the power supply voltage Vcc generated at the power supply terminal 20C is activated, and the regulator 215 is started up. When the output voltage of the regulator 215 reaches a predetermined voltage, the startup circuit 214 stops generating the startup current Id.

The startup circuit 214 includes a current source 214A configured to generate the startup current Id and shunt the constant current Ia. Generation of the constant current Ia is started when the startup circuit 214 is started up. Even in a case where the generation of the startup current Id is stopped as described above, the generation of the constant current Ia is continued. As described above, the constant current Ia is mirrored by the current mirror 211 to become the constant current output Ib. An area for configuring the current mirror 211 and the current source 214A inside the startup circuit 214 becomes small.

### 4. Modification

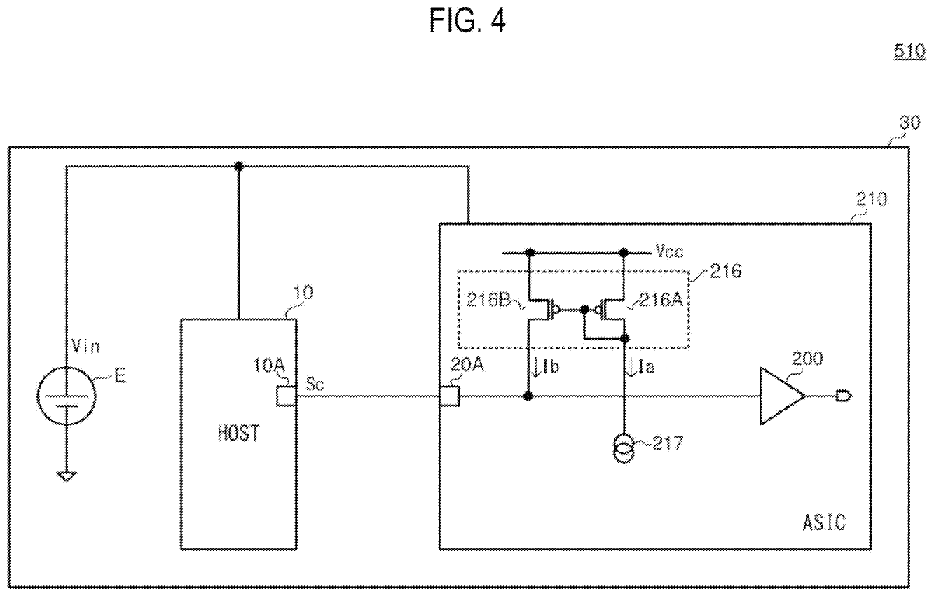

FIG. 4 is a diagram showing a configuration of a semiconductor device system 510 according to a modification. In the semiconductor device system 510, the ASIC 210 includes a current mirror 216 and a constant current source 217.

The current mirror 216 includes an input stage 216A and an output stage 216B. Both the input stage 216A and the output stage 216B are constituted by PMOS transistors. A drain of the input stage 216A is connected to the constant current source 217. The drain of the output stage 216B is connected to the control input terminal 20A.

In the semiconductor device system 510, the ASIC 21 is in a disabled state when the control input signal Sc is at a high level, and the ASIC 21 is in an enabled state when the control input signal Sc is at a low level. The constant current Ia flowing through the input stage 216A by the constant current source 217 is mirrored by the current mirror 216 to become a constant current output Ib flowing through the output stage 216B. Since electric charges are supplied to the control input terminal 20A by the constant current output Ib, the voltage at the control input terminal 20A is set to a high level, and an unstable state is suppressed. Further, the generated current becomes a constant current regardless of the voltage level at the control input terminal 20A. A circuit area of the current mirror 216 and the constant current source 217 configured to realize a constant current with a small current value is small. Therefore, low current consumption may be achieved in the ASIC 210.

### 5. Application Example

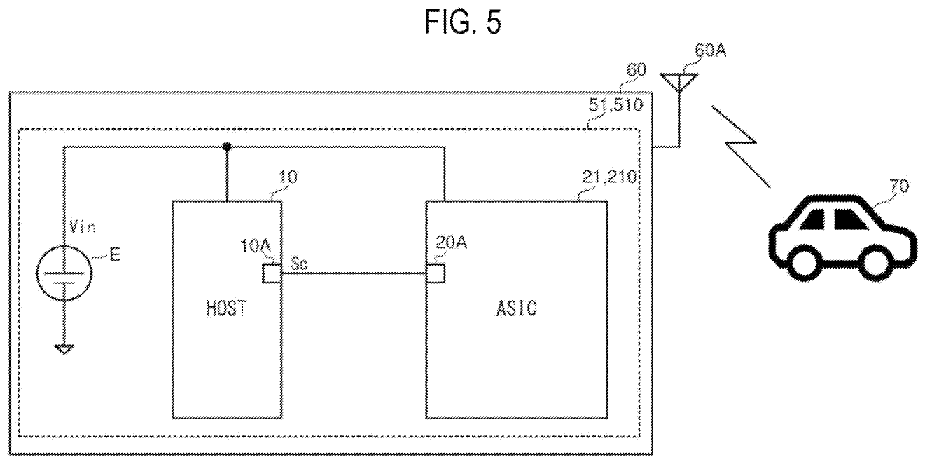

FIG. 5 is a diagram illustrating a configuration of an electronic key 60 which is an example of an application to which the semiconductor device system 51 or 510 according to an embodiment of the present disclosure is applied. The electronic key 60 is a mobile device that is used in a key entry system and is configured to lock and unlock doors of a vehicle 70 by remote control.

The electronic key 60 includes the semiconductor device system 51 or 510 and an antenna 60A. The ASIC 21 or 210 performs wireless communication with the vehicle 70 via the antenna 60A.

### 6. Others

Various technical features disclosed in the present disclosure are not limited to the above-described embodiments but may be modified in various forms without departing from the spirit of its technical creation. That is, the above-described embodiments should be considered as being exemplary in all respects and not limitative. It should be understood that the technical scope of the present disclosure is not limited to the above-described embodiments, and encompasses all changes that fall within meaning and range equivalent to the claims.

### 7. Supplementary Note

As described above, a semiconductor device (21) according to an aspect of the present disclosure includes:
a control input terminal (20A) configured to receive a control input signal (Sc) from an external controller (10); and
a current mirror (211) including an input stage (211A) and an output stage (211B) connected to the control input terminal (first configuration).

Further, in the first configuration, both the input stage and the output stage may be constituted by NMOS transistors (second configuration).

Further, in the first configuration, both the input stage and the output stage may be constituted by PMOS transistors (third configuration).

Further, in any one of the first to third configurations, the semiconductor device (21) may further include:
a circuit current source (213) configured to generate a circuit current (Ic2) which is to be supplied to an internal circuit of the semiconductor device,
wherein a current (Ia) shunted by the circuit current source may be supplied to the input stage (fourth configuration).

Further, in any one of the first to third configurations, the semiconductor device (21) may further include:
a startup circuit (214) configured to generate a startup current (Id) for starting up to generate a power supply voltage (Vcc) when an input voltage (Vin) inputted from an outside of the semiconductor device is activated,
wherein even when the generation of the startup current is stopped, generation of a current (Ia) shunted by the startup circuit and supplied to the input stage may be continued (fifth configuration).

Further, a semiconductor device system (51) according to an aspect of the present disclosure includes: the semiconductor device (21) of any one of the first to fifth configurations; and the controller (10) (sixth composition).

Further, in the sixth configuration, the semiconductor device and the controller may be driven by a battery (seventh configuration).

Furthermore, a mobile device (60) according to an aspect of the present disclosure includes the semiconductor device system of the seventh configuration (eighth configuration).

The present disclosure may be used, for example, in mobile devices such as an electronic key and the like.

According to the present disclosure in some embodiments, it is possible to effectively realize low current consumption.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a control input terminal configured to receive a control input signal from an external controller; and
a current mirror including an input stage and an output stage connected to the control input terminal.

2. The semiconductor device of claim 1, wherein both the input stage and the output stage are constituted by NMOS transistors.

3. The semiconductor device of claim 1, wherein both the input stage and the output stage are constituted by PMOS transistors.

4. The semiconductor device of claim 1, further comprising:
a circuit current source configured to generate a circuit current which is to be supplied to an internal circuit of the semiconductor device,
wherein a current shunted by the circuit current source is supplied to the input stage.

5. The semiconductor device of claim 1, further comprising:
a startup circuit configured to generate a startup current for starting up to generate a power supply voltage when an input voltage inputted from an outside of the semiconductor device is activated,
wherein even when the generation of the startup current is stopped, generation of a current shunted by the startup circuit and supplied to the input stage is continued.

6. A semiconductor device system, comprising:
the semiconductor device of claim 1; and
the controller.

7. The semiconductor device system of claim 6, wherein the semiconductor device and the controller are driven by a battery.

8. A mobile device, comprising the semiconductor device system of claim 7.
